(19) United States
(12) Patent Application Publication
(10) Pub. No.: US 2026/0059829 A1
(43) Pub. Date: Feb. 26, 2026

(54) Inner Spacer of Multi-Gate Devices and Methods of Forming Same

(71) Applicant: Taiwan Semiconductor Manufacturing Company, Ltd., Hsin-Chu (TW)

(72) Inventors: Hsuan-Hsiao YAO, Hsinchu City (TW); Ying-Zhu HUANG, Yilan County (TW); Tsai-Yu HUANG, Hsinchu City (TW); Yen-Chun HUANG, Taipei City (TW)

(21) Appl. No.: 18/813,292

(22) Filed: Aug. 23, 2024

(51) Int. Cl. H01L 29/66; H01L 21/324; H01L 21/8234; H01L 27/088; H01L 29/06; H01L 29/423; H01L 29/775; H01L 29/786

(52) U.S. Cl. CPC H10D 64/018; H01L 21/324; H10D 30/014; H10D 30/43; H10D 30/6735; H10D 30/6757; H10D 62/121; H10D 64/017; H10D 84/013; H10D 84/0135; H10D 84/038; H10D 84/83

(57) ABSTRACT

A method includes providing a workpiece. The workpiece includes a stack of channel layers and sacrificial layers, a dummy gate structure disposed over the stack, and a source/drain trench adjacent to the stack and the dummy gate structure. The method further includes replacing the sacrificial layers with a first dummy layer and a second dummy layer. The second dummy layer is spaced apart from the channel layers by the first dummy layer. The method further includes selectively and partially recessing the first dummy layer and the second dummy layer to form inner spacer recesses among the channel layers, forming inner spacer features in the inner spacer recesses, forming a source/drain feature in the source/drain trench, and replacing the dummy gate structure, the first dummy layer, and the second dummy layer with a metal gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

However, despite having many desirable features, multi-gate device fabrication has continued to face challenges as a result of the ongoing scaling down of semiconductor IC dimensions. Thus, existing techniques have not proved entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1 and 2 illustrate a flowchart of a method for forming a semiconductor structure, according to one or more aspects of the present disclosure.

FIGS. 3, 4, 5, 6, 7, 8, 9, 10, 11, 12, 13, 14, 15, 17, 18, 20, 21, 22, 23, 24, and 25 illustrate fragmentary cross-sectional views of an exemplary semiconductor structure during various fabrication stages in the method of FIG. 1 and/or FIG. 2, according to one or more aspects of the present disclosure.

FIGS. 16A, 16B, and 16C illustrate enlarged views of a portion in FIG. 15, according to one or more aspects of the present disclosure.

FIGS. 19A, 19B, and 19C illustrate enlarged views of a portion in FIG. 18, according to one or more aspects of the present disclosure.

FIGS. 26A, 26B, and 26C illustrate enlarged views of a portion in FIG. 25, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

As described above, MBC transistors may also be referred to as SGTs, GAA transistors, nanosheet transistors, or nanowire transistors. They can be either n-type or p-type. MBC devices may have channel regions disposed in nanowire channel members, bar-shaped channel members, nanosheet channel members, nanostructure channel members, bridge-shaped channel members, and/or other suitable channel configurations. GAA transistors may be fabricated using a replacement gate process, where a dummy gate stack is formed first as a placeholder and is subsequently replaced with a functional gate structure. In some replacement gate processes, sacrificial materials among nanostructures of the GAA transistor are removed after epitaxial source/drain features are formed. During the removal of the sacrificial materials, inner spacer features function to contain the etching process to define a profile of the gate structure and to protect the epitaxial source/drain features from being etched. Different inner spacer profiles may be desired for different devices. While existing techniques are generally adequate for their intended purposes, they are not satisfactory in all aspects.

The present disclosure provides methods for forming a semiconductor device such as a GAA transistor. In an example process, a fin-shaped structure with channel layers and sacrificial layers is formed over a substrate. After formation of a dummy gate stack over a channel region of the fin-shaped structure, at least one gate spacer is formed over the dummy gate stack. Source/drain regions of the fin-shaped structure are recessed. The sacrificial layers are selectively removed to release the channel layers as channel members. A first dummy layer is deposited to wrap around each of the channel members. A second dummy layer is then deposited to fill the remaining space between neighboring channel members. A thermal operation may be performed to modify etch resistance(s) of the first dummy layer and/or the second dummy layer. The first dummy layer and the second dummy layer are then selectively and partially recessed to form inner spacer recesses between the plurality of channel members. The recessing may etch the second dummy layer at a same or faster rate than it etches the first dummy layer, thereby forming various profiles of the inner spacer recesses. Inner spacer features are formed in the inner spacer recesses. Source/drain features are then formed over the source/drain recesses. After selective removal of the dummy gate stack, the dummy layer is selectively removed to release the channel members again. A gate structure is then formed to wrap around each of the channel members. By having the first dummy layer and the second dummy layer and modifying their etch resistance(s), the profiles of the inner spacer features may be controlled, thus overall performance of the semiconductor device may be improved.

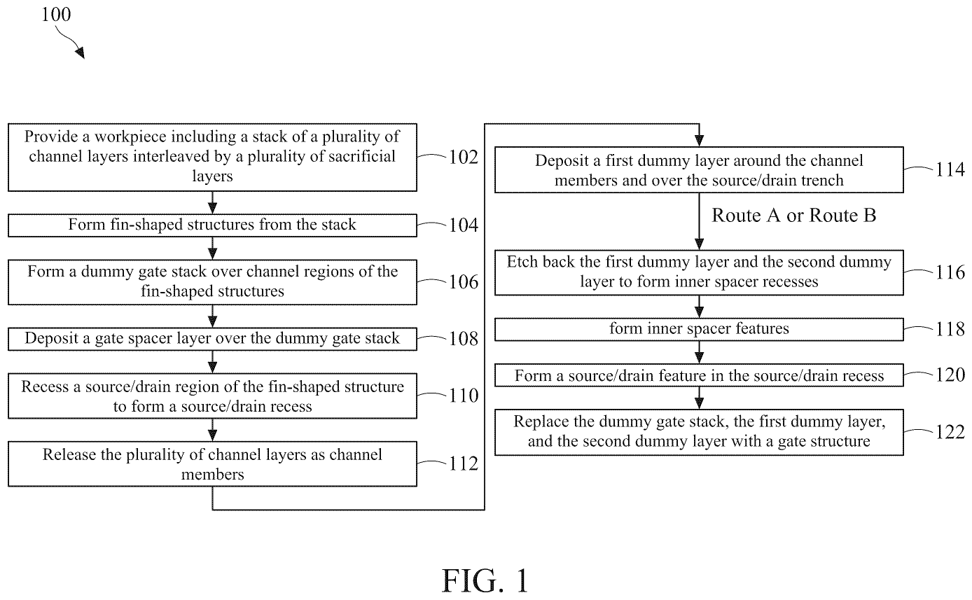

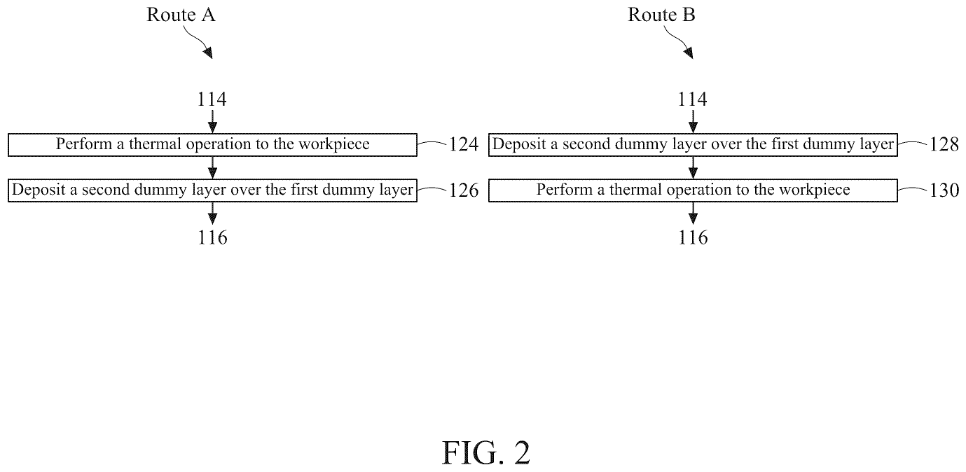

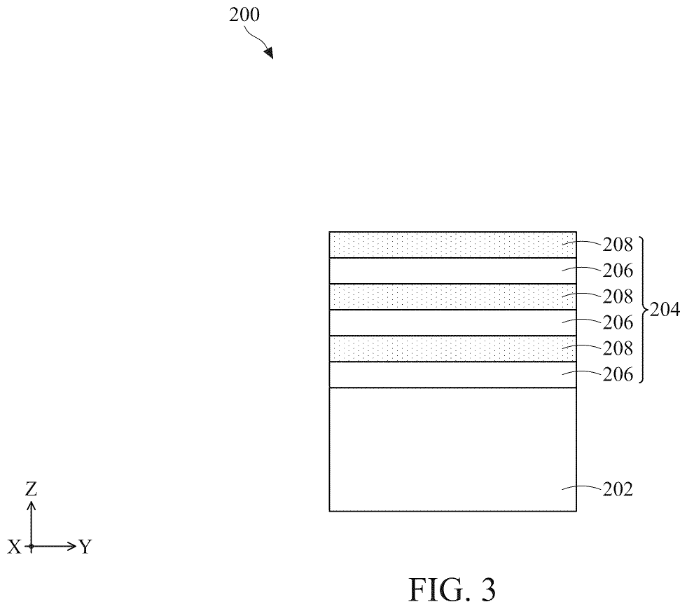

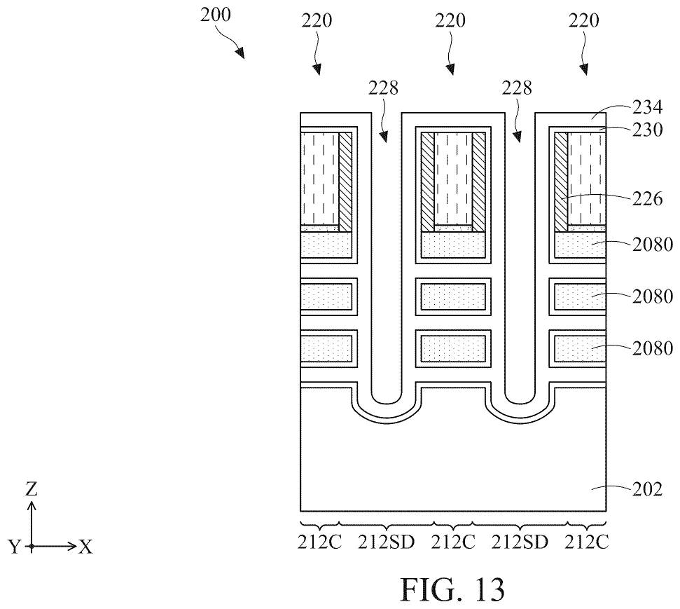

The various aspects of the present disclosure will now be described in more detail with reference to the figures. In that regard, FIG. 1 is a flowchart illustrating method 100 of forming a semiconductor structure according to embodiments of the present disclosure. FIG. 2 is a flowchart illustrating route A and route B, which are a portion of method 100 as in FIG. 1. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 3-26C, which are fragmentary cross-sectional views of a workpiece 200 at different stages of fabrication according to embodiments of method 100 in FIGS. 1 and 2. Because the workpiece 200 will be fabricated into a semiconductor structure or a semiconductor device, the workpiece 200 may be referred to herein as a semiconductor structure 200 or a semiconductor device 200 as the context requires. For avoidance of doubts, the X, Y and Z directions in FIGS. 3-26C are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Further, the semiconductor structures disclosed herein may include various other devices and features, such as other types of devices including additional transistors, bipolar junction transistors, resistors, capacitors, inductors, diodes, fuses, SRAM and/or other logic circuits, etc., but are simplified for a better understanding of the inventive concepts of the present disclosure. In some embodiments, the exemplary devices include a plurality of semiconductor devices (e.g., transistors), including n-type GAA transistors, p-type GAA transistors, PFETs, NFETs, etc., which may be interconnected.

Referring to FIGS. 1 and 3, method 100 includes a block 102 where a workpiece 200 is provided. As shown in FIG. 3, the workpiece 200 includes a substrate 202 and a stack 204 of alternating semiconductor layers formed over the substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SIC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 3, which is for illustrative purposes only and not intended to be limiting beyond what is specifically recited in the claims. It can be appreciated that any number of epitaxial layers may be formed in the stack 204. The number of layers depends on the desired number of channel members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

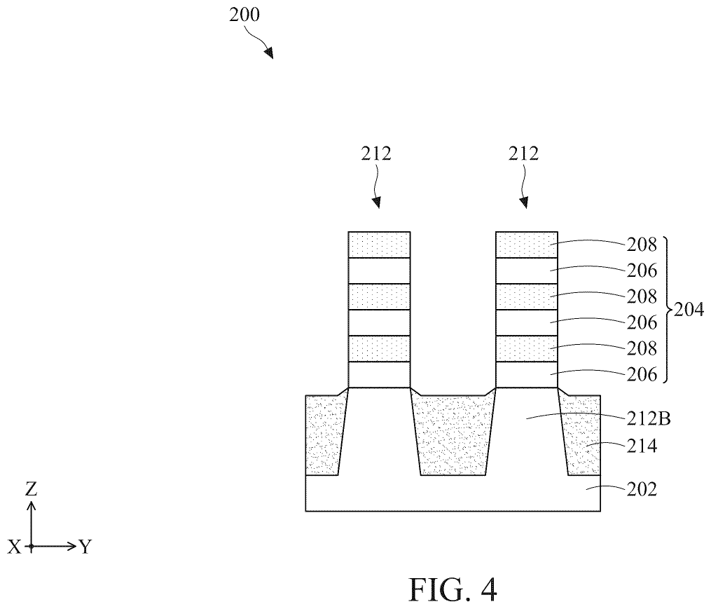

Referring to FIGS. 1 and 4, method 100 includes a block 104 where a fin-shaped structure 212 (also referred to as an active region 212) is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 4, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 4, the fin-shaped structure 212 that includes the sacrificial layers 206 and the channel layers 208 extends vertically along the Z direction and lengthwise along the X direction. As shown in FIG. 4, the fin-shaped structure 212 includes a base fin structure 212B patterned from the substrate 202. The patterned stack 204, including the sacrificial layers 206 and the channel layers 208, is disposed directly over the base fin structure 212B.

An isolation feature 214 is formed adjacent to the fin-shaped structure 212. In some embodiments represented in FIG. 4, the isolation feature 214 is disposed on sidewalls of the base fin structure 212B. In some embodiments, the isolation feature 214 may be formed in the trenches to isolate the fin-shaped structures 212 from a neighboring fin-shaped structure 212. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 4. The fin-shaped structure 212 rises above the STI feature 214 after the recessing, while the base fin structure 212B is embedded or buried in the isolation feature 214.

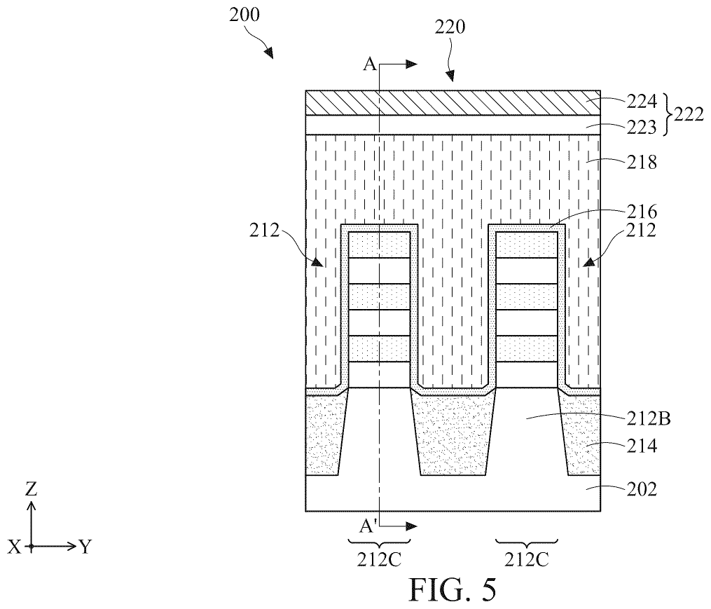

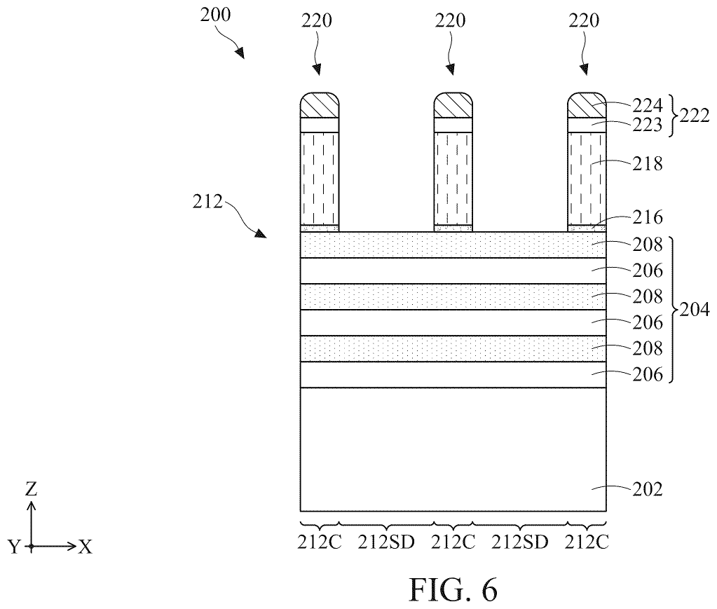

Referring to FIGS. 1, 5, and 6, method 100 includes a block 106 where a dummy gate stack 220 is formed over a channel region 212C of the fin-shaped structure 212. FIG. 6 illustrates a fragmentary cross-section view of the workpiece 200 taken along line A-A′ as in FIG. 5. In some embodiments, a gate replacement process (or gate-last process) is adopted where the dummy gate stack 220 (shown in FIGS. 5 and 6) serves as a placeholder to undergo various processes and is to be removed and replaced by a functional gate structure. Other processes and configuration are possible. In some embodiments illustrated in FIG. 6, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 6, the channel region 212C is disposed between two source/drain regions 212SD along the X direction.

The formation of the dummy gate stack 220 may include deposition of layers in the dummy gate stack 220 and patterning of these layers. Referring to FIG. 5, a dummy dielectric layer 216, a dummy electrode layer 218, and a gate-top hard mask layer 222 may be blanketly deposited over the workpiece 200. In some embodiments, the dummy dielectric layer 216 may be formed on the fin-shaped structure 212 using a chemical vapor deposition (CVD) process, an atomic layer deposition (ALD) process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 6. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 6, the dummy gate stack 220 is patterned such that it is only disposed over the channel region 212C, not disposed over the source/drain region 212SD.

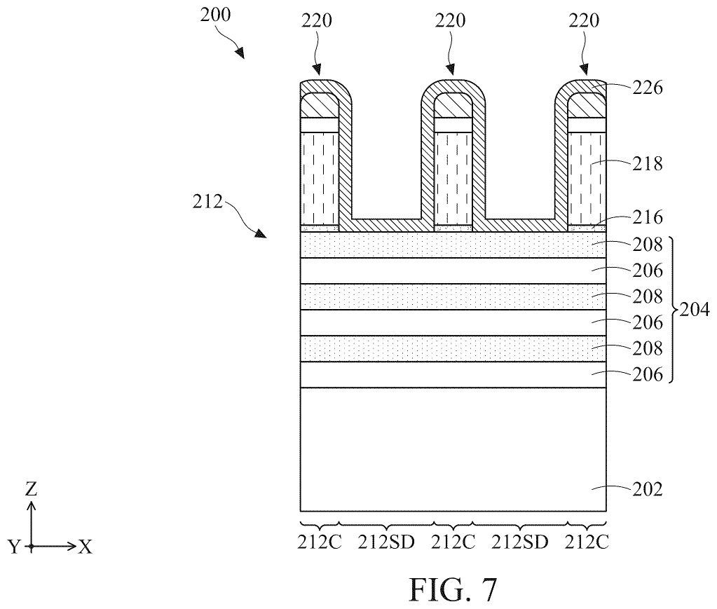

Referring to FIGS. 1 and 7, method 100 includes a block 108 where a gate spacer layer 226 is deposited over the workpiece 200, including over the dummy gate stack 220. In some embodiments, the gate spacer layer 226 is deposited conformally over the workpiece 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

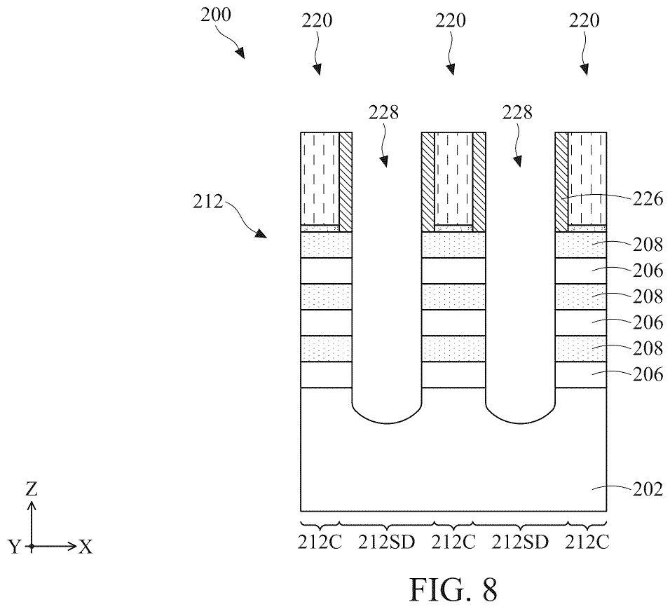

Referring to FIGS. 1 and 8, method 100 includes a block 110 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 8, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202.

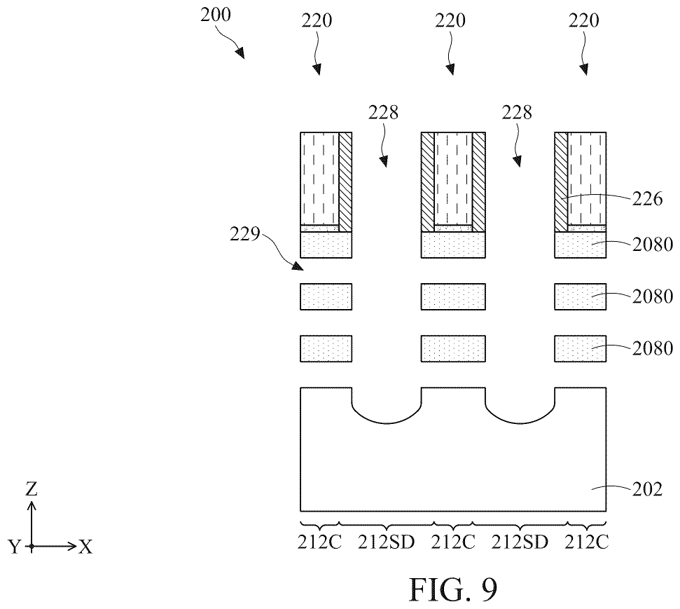

Referring to FIGS. 1 and 9, method 100 includes a block 112 where the plurality of channel layers 208 in the channel regions are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 8) to form channel members 2080 shown in FIG. 9. The selective removal of the sacrificial layers 206 forms spaces 229 between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Depending on the design, the channel members 2080 may take form of nanowires, nanosheets, or other nanostructures.

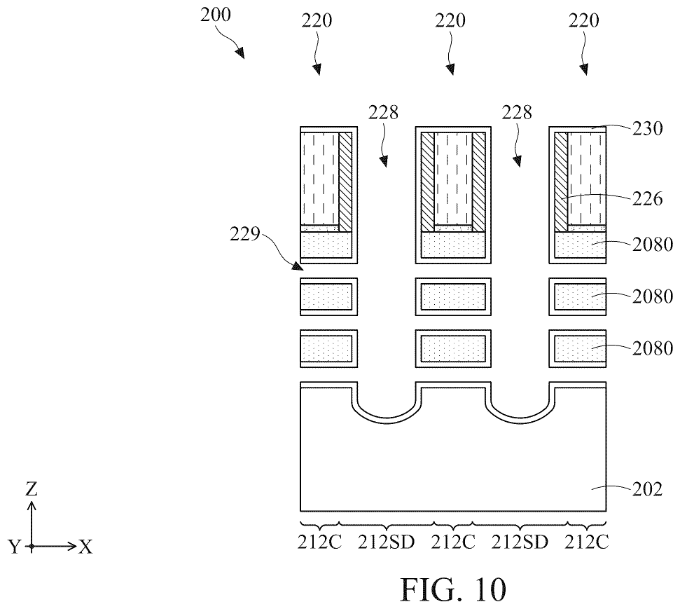

Referring to FIGS. 1 and 10, method 100 includes a block 114 where a first dummy layer 230 is deposited around the channel members 2080 and over the source/drain trench 228. The first dummy layer 230 may include a dielectric material (e.g., a first oxide material) and may be deposited using plasma enhanced chemical vapor deposition (PECVD) or ALD. In some embodiments, the dielectric material includes a nitride. Depositing the first dummy layer 230 may be at a temperature of lower than about 500° C., alternatively lower than about 400° C. In some embodiments, the first oxide material includes silicon oxide, such as silicon dioxide, silicon monoxide, or a combination thereof. In some embodiments, the first dummy layer 230 includes silicon dioxide of greater than about 95% and silicon monoxide of less than about 5%. As shown in FIG. 10, the first dummy layer 230 may be deposited around exposed surfaces of the channel members 2080 and partially fill the spaces 229. Additionally, the first dummy layer 230 may be in direct contact with a sidewall of the gate spacer layer 226 and a top surface of the substrate 202. The first dummy layer 230 may also cover top surfaces of the dummy gate stack 220 and the gate spacer layer 226. The first dummy layer 230 may be deposited conformally. The first dummy layer 230 may have a thickness of about 1 nm to about 3 nm.

Referring to FIGS. 1, 2, and 11, in some embodiments, method 100 includes route A proceeding from block 114. Route A includes a block 124 where a thermal operation 232 is performed to the workpiece 200. The thermal operation 232 may modify properties and/or compositions of the first dummy layer 230, and after the thermal operation 232, the first dummy layer 230 may also be referred to as a first dummy layer 230′ or a modified first dummy layer 230′. In some embodiments, the thermal operation 232 is in an atmosphere that includes a reactive gas, an inert gas (e.g., nitrogen, argon), or a combination thereof. The reactive gas may include a gas providing active nitrogen, a gas providing active oxygen, or a combination thereof. The reactive gas may react with the first dummy layer 230 (e.g., increasing nitrogen and/or oxygen concentration in the first dummy layer 230) and thus increase etch resistance of the first dummy layer 230. Etch resistance in this disclosure refers to etch resistance in the following operations, for example, operations at block 116. In some embodiments, the gas providing active nitrogen includes ammonia (NH₃), organic amines, organic amides, hydrazine, nitrogen (N₂) radical, nitrogen (N₂) plasma, ammonia radical, ammonia plasma, and nitric oxide (NO). In some embodiments, the gas providing active nitrogen includes NH₃. In some embodiments, the gas providing active oxygen includes oxygen (O₂). The thermal operation 232 may include annealing processes (e.g., rapid thermal annealing (RTA) and/or laser annealing) and/or a radical treatment. In some embodiments, the thermal operation 232 is at a first temperature of about 700° C. to about 1200° C. for a first time duration of about 0.2 microseconds (ms) to about 300 seconds. The first temperature may be greater than the temperature during operations at block 114. In some embodiments, etch resistance of the first dummy layer 230 is increased during the thermal operation 232. In other words, the modified first dummy layer 230′ has greater etch resistance compared to the first dummy layer 230. In some embodiments, the first dummy layer 230 densifies and shrinks during the thermal operation 232. Thus, the thickness of the first dummy layer 230 may decreases during the thermal operation 232. A thickness of the modified first dummy layer 230′ may be about 0.5 nm to about 3 nm.

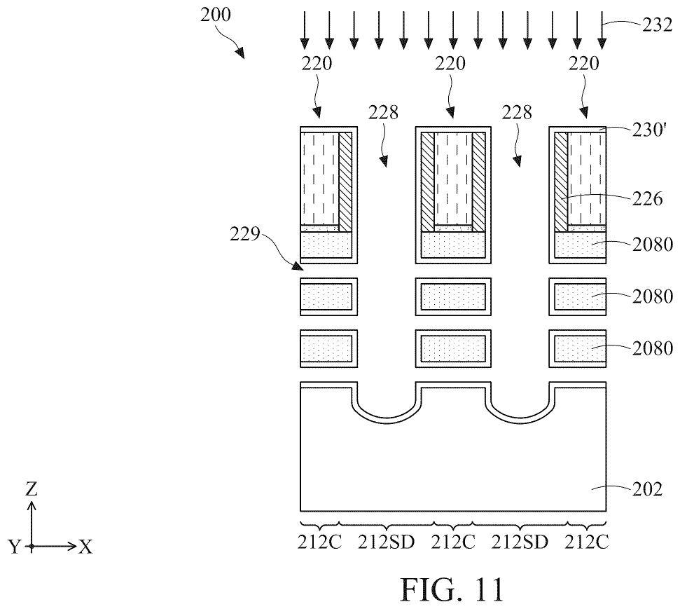

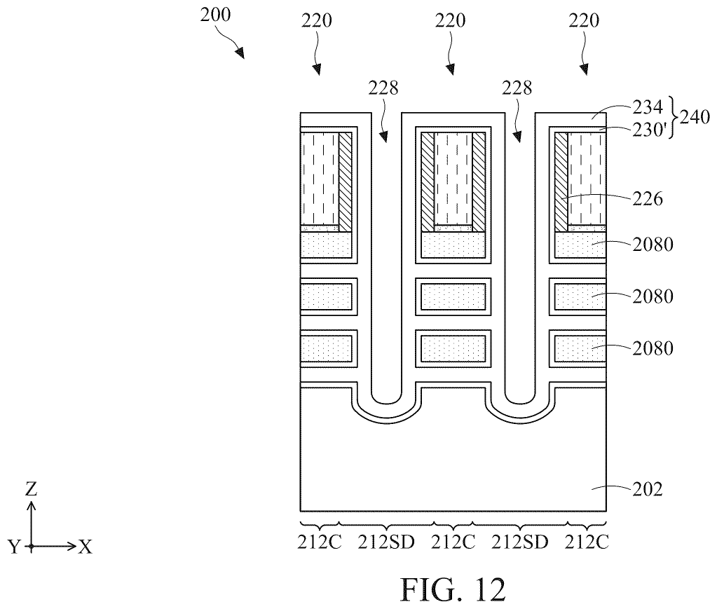

Referring to FIGS. 1, 2, and 12, route A includes a block 126 where a second dummy layer 234 is deposited over the modified first dummy layer 230′. As shown in FIG. 12, the second dummy layer 234 may be deposited over exposed surfaces of the modified first dummy layer 230′ and fill the spaces 229 among the channel members 2080 as in FIG. 11. The second dummy layer 234 may include a dielectric material (e.g., a second oxide material) and may be deposited using plasma enhanced chemical vapor deposition (PECVD), ALD, or flowable CVD (FCVD). In some embodiments, operations at block 126 introduces precursors such as a silicon-containing compound and an oxygen-containing compound. The silicon-containing compound and the oxygen-containing compound may react to form the second dummy layer 234. Depositing the second dummy layer 234 may be at a temperature of lower than about 500° C., alternatively lower than about 400° C. In some embodiments, the second oxide material includes silicon oxide, such as silicon dioxide, silicon monoxide, or a combination thereof. In some embodiments, the second dummy layer 234 includes silicon dioxide of greater than about 95% and silicon monoxide of less than about 5%. The second dummy layer 234 may include a higher concentration of impurities (i.e., components other than silicon dioxide and silicon oxide, e.g., from precursors) than the first dummy layer 230. The second dummy layer 234 may include a higher concentration of hydrogen and a lower concentration of nitrogen than the first dummy layer 230. In some embodiments, the second dummy layer 234 is more flowable compared to the first dummy layer 230 or the modified first dummy layer 230′, and the second oxide material includes a flowable oxide. The second dummy layer 234 may have a smaller density than the first dummy layer 230 or the modified first dummy layer 230′. Etch resistance of the second dummy layer 234 may be less than etch resistance of the first dummy layer 230 or etch resistance of the modified first dummy layer 230′. The second dummy layer 234 may have a greater thickness compared to the first dummy layer 230 or the modified first dummy layer 230′.

Referring to FIGS. 1, 2, and 13, in some alternative embodiments, method 100 includes route B proceeding from block 114. Route B includes a block 128 where a second dummy layer 234 similar as described above is deposited over the first dummy layer 230. A difference from the operations at block 126 includes that, instead of being deposited over the modified first dummy layer 230′, the second dummy layer 234 may be deposited over exposed surfaces of the first dummy layer 230 and fill the spaces 229 among the channel members 2080 as in FIG. 10.

Referring to FIGS. 1, 2, and 14, route B includes a block 130 where a thermal operation 236 is performed to the workpiece 200. The thermal operation 236 may be similar to the thermal operation 232 at block 124 as described above. Differences from the thermal operation 232 are as follows. The thermal operation 236 may modify properties and/or compositions of the first dummy layer 230 and the second dummy layer 234. After the thermal operation 236, the first dummy layer 230 may also be referred to as a first dummy layer 230′ or a modified first dummy layer 230′ (similar to the modified first dummy layer 230′ after the thermal operation 232), and the second dummy layer 234 may also be referred to as a second dummy layer 234′ or a modified second dummy layer 234′. The modified second dummy layer 234′ may be less flowable compared to the second dummy layer 234. The modified first dummy layer 230′ may have a greater density than the modified second dummy layer 234′. A nitrogen concentration in the modified first dummy layer 230′ may be greater than a nitrogen concentration in the modified second dummy layer 234′. The reactive gas may react with the second dummy layer 234 (e.g., increasing nitrogen and/or oxygen concentration in the second dummy layer 234) and increase etch resistance of the second dummy layer 234. In some embodiments, the reactive gas does not react with the first dummy layer 230. The thermal operation 236 may be at a second temperature for a second time duration. Because of existing of the second dummy layer 234, the second temperature may be greater than the first temperature and/or the second time duration may be greater than the first time duration. In some embodiments, the second temperature is about 800° C. to about 1300° C. The second temperature may be greater than the temperature during operations (e.g., depositing the first dummy layer 230) at block 114 and the temperature during operations (e.g., depositing the second dummy layer 234) at block 126 or 128. In some embodiments, etch resistance of the first dummy layer 230 and etch resistance of the second dummy layer 234 are increased during the thermal operation 236. In other words, the modified first dummy layer 230′ has a greater etch resistance compared to the first dummy layer 230, and the modified second dummy layer 234′ has a greater etch resistance compared to the second dummy layer 234. In some embodiments, the first dummy layer 230 and the second dummy layer 234 densify and shrink during the thermal operation 236. Thus, the thicknesses of the first dummy layer 230 and the second dummy layer 234 may decrease during the thermal operation 236.

In some alternative embodiments, route A may further include the block 130 between the blocks 126 and 116. In such embodiments, the first dummy layer 230 undergoes both the thermal operations 232 and 236, thus may further increase its etch resistance; the second dummy layer 234 undergoes the thermal operation 236. In some other embodiments, both the thermal operations 232 and 236 are omitted, thus etch resistance differences between the first dummy layer 230 and the second dummy layer 234 may be essentially from differences in the materials thereof.

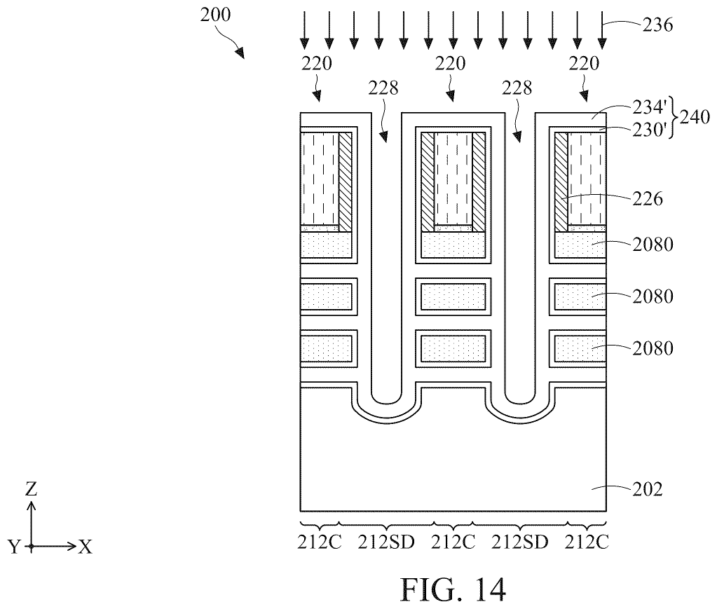

Referring to FIGS. 1, 2, and 15-16C, method 100 includes a block 116 proceeding from route A or route B. At block 116, the first dummy layer 230/230′ and the second dummy layer 234/234′ (modified or unmodified, collectively referred to as a combined dummy layer 240) are selectively and partially recessed to form inner spacer recesses 238, while the gate spacer layer 226, the dummy gate stack 220, the exposed portion of the substrate 202, and the channel members 2080 are substantially unetched. When route A is taken, the modified first dummy layer 230′ and the second dummy layer 234 as in FIG. 12 collectively form the combined dummy layer 240. When route B is taken, the modified first dummy layer 230′ and the modified second dummy layer 234′ as in FIG. 14 collectively form the combined dummy layer 240. The combined dummy layer 240 may also be removed from sidewalls of the gate spacer layer 226 and the channel members 2080, and top surfaces of the dummy gate stack 220, the gate spacer layer 226, and source/drain regions 212SD. In some embodiments, the selective recess of the combined dummy layer 240 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid (e.g., a dilute hydrofluoric acid (DHF)), ammonium fluoride, or a mixture thereof. An example selective wet etching process may include an APM etch (e.g., ammonia hydroxide-hydrogen peroxide-water mixture).

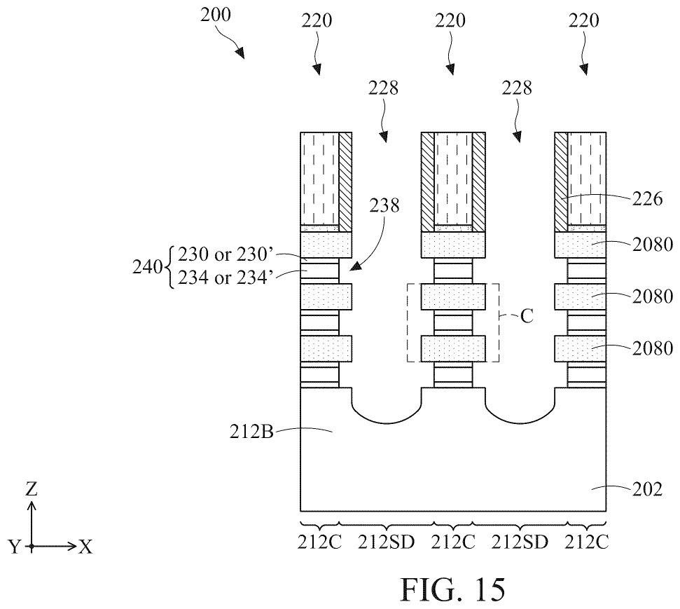

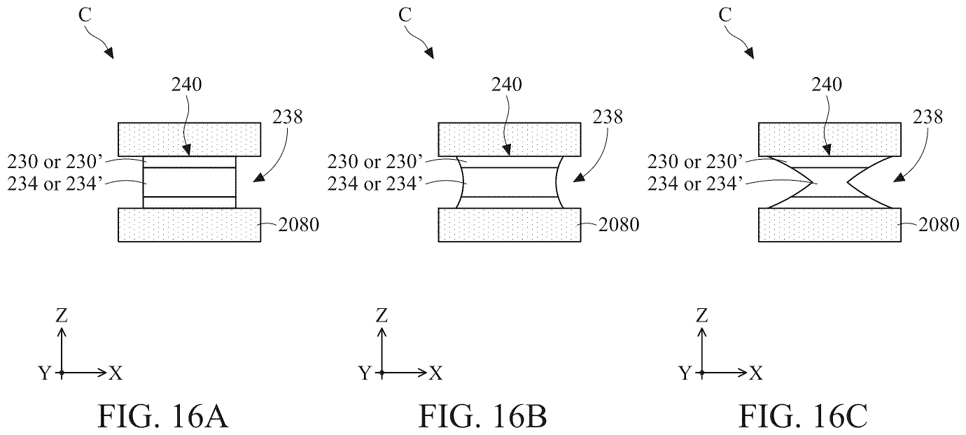

FIGS. 16A-16C illustrate enlarged views of a portion C (an example portion including two neighboring channel members 2080 and structures therebetween) in the dotted rectangle of the workpiece 200 as in FIG. 15. In some embodiments, during the selective etching process, the first dummy layer 230 (or the modified first dummy layer 230′) has a first etch rate, and the second dummy layer 234 (or the modified second dummy layer 234′) has a second etch rate equal to or greater than the first etch rate. In some embodiments as in FIG. 16A, the first etch rate is about the same as the second etch rate. In such embodiments, the inner spacer recesses 238 each have a rectangular shape in the cross-sectional view. In some other embodiments, the first etch rate is less than the second etch rate, which may lead to an over-etch of the second dummy layer 234 (or 234′) and an under-etch of the first dummy layer 230 (or 230′). In some embodiments as in FIG. 16B, a ratio of the first etch rate to the second etch rate is less than about 1:1 and greater than about 1:2. In such embodiments, the inner spacer recesses 238 may each have a U-shape in the cross-sectional view. In some embodiments as in FIG. 16C, a ratio of the first etch rate to the second etch rate is about 1:2 to about 1:5. In such embodiments, the inner spacer recesses 238 may each have a V-shape in the cross-sectional view.

A ratio of the first etch rate to the second etch rate may be controlled by selecting materials of the first dummy layer 230 and the second dummy layer 234, selecting a manufacturing route (e.g., route A or route B of method 100), controlling operating conditions (e.g., time duration, atmosphere gas, temperature) of the thermal operation 232 and/or 236, and/or controlling the selective etching process at block 116. Route A may result in a first ratio of the first etch rate to the second etch rate, and route B may result in a second ratio of the first etch rate to the second etch rate. The first ratio may be less than the second ratio. In some embodiments, the workpiece 200 undergoes route A and the inner spacer recesses 238 have a profile as in FIG. 16C. In some embodiments, the workpiece 200 undergoes route B and the inner spacer recesses 238 have a profile as in FIG. 16A or FIG. 16B. In some embodiments, the workpiece 200 undergoes route B and the inner spacer recesses 238 have a profile as in FIG. 16A.

Referring to FIGS. 1 and 17-19C, method 100 includes a block 118 where inner spacer features 246 are formed in the inner spacer recesses 238. Operation at block 118 may include deposition of an inner spacer material 244 over the workpiece 200, and etching back the inner spacer material 244 to form the inner spacer features 246 in the inner spacer recesses 238 as shown in FIGS. 15-16C.

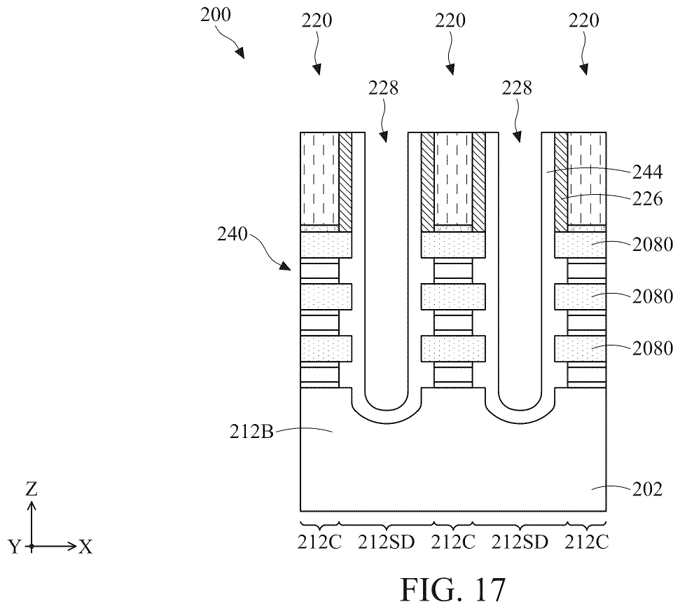

Referring to FIG. 17, the inner spacer material 244 is deposited over the workpiece 200, including over the inner spacer recesses 238. The inner spacer material 244 may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. The inner spacer material 244 may have a different composition than the combined dummy layer 240. While not explicitly shown, the inner spacer material 244 may be a single layer or a multilayer. In some implementations, the inner spacer material 244 may be deposited using CVD, PECVD, SACVD, ALD or other suitable methods. The inner spacer material 244 is deposited into the inner spacer recesses 238 as well as over the sidewalls of the channel members 2080 exposed in the source/drain trenches 228.

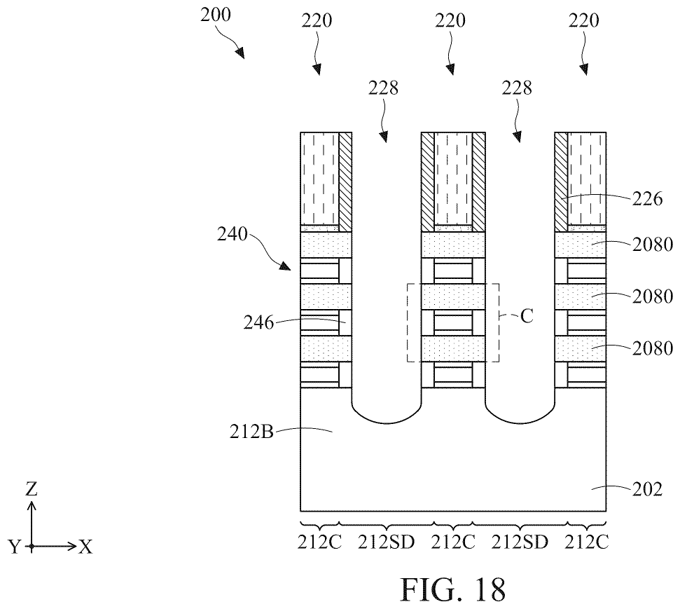

Referring to FIG. 18, the deposited inner spacer material 244 is then etched back to remove the inner spacer material 244 from the sidewalls of the channel members 2080 to form the inner spacer features 236 in the inner spacer recesses 238. At block 118, the inner spacer material 244 may also be removed from the top surfaces and/or sidewalls of the dummy gate stack 220 and the gate spacer layer 226. As shown in FIG. 18, each of the inner spacer features 246 is in direct contact with the recessed combined dummy layer 240 and is disposed vertically (along the Z direction) between two neighboring channel members 2080.

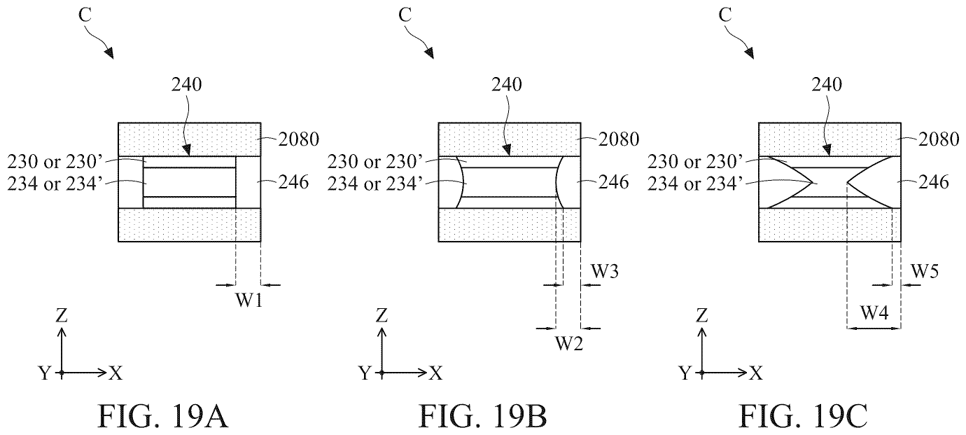

FIGS. 19A-19C illustrate enlarged views of the portion C in the dotted rectangle of the workpiece 200 as in FIG. 18 and correspond to structures presented in FIGS. 16A-16C, respectively. The inner spacer features 246 in FIGS. 19A-19C track the shape of the inner spacer recesses 238 as in FIG. 16A-16C, respectively. In the depicted embodiments, outer sidewalls of the inner spacer features 246 align with sidewalls of the channel members 2080. In some other embodiments not depicted, the outer sidewalls of the inner spacer features 246 do not align with the sidewalls of the channel members 2080. In the depicted embodiment in FIG. 19A, the inner spacer features 246 each have a width W1 of about 3 nm to about 8 nm. In the depicted embodiment in FIG. 19B, the inner spacer features 246 each have a width W2 of about 3 nm to about 10 nm. The U-shaped inner spacer features 246 may each have an interface with the top or bottom channel member 2080, and the interface may have a width W3 as depicted. W3 may be of about 1 nm to about 7 nm. In the depicted embodiment in FIG. 19C, the inner spacer features 246 each have a width W4 of about 3 nm to about 12 nm. The V-shaped inner spacer features 246 may each have an interface with the top or bottom channel member 2080, and the interface may have a width W5 as depicted. W5 may be of about 1 nm to about 7 nm. Surfaces of the inner spacer feature 246 interfacing the combined dummy layer 240 in FIG. 19C may each have a slightly convex profile, and collectively form the V-shape.

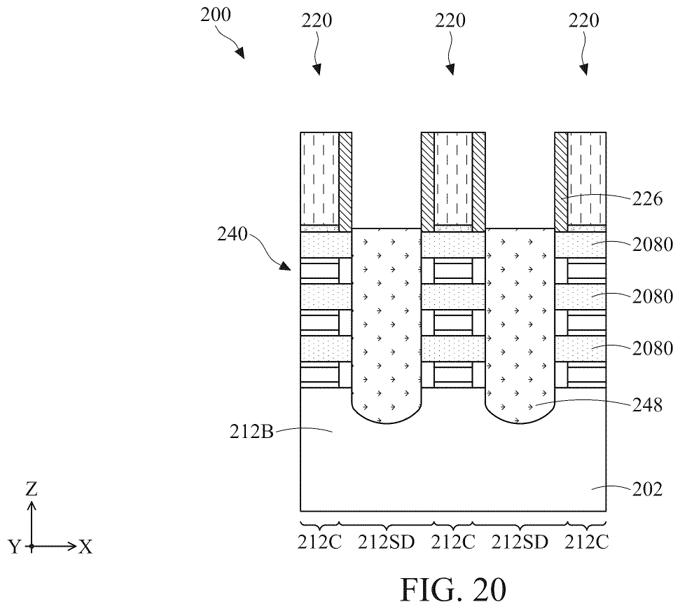

Referring to FIGS. 1 and 20, method 100 includes a block 120 where a source/drain feature 248 is formed over the source/drain region 212SD. While not explicitly shown, before any of the epitaxial layers are formed, method 100 may include a cleaning process to clean surfaces of the workpiece 200. The cleaning process may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

In some embodiments, the source/drain features 248 may be formed using an epitaxial process, such as vapor-phase epitaxy (VPE), ultra-high vacuum CVD (UHV-CVD), molecular beam epitaxy (MBE), and/or other suitable processes. The epitaxial growth process may use gaseous and/or liquid precursors, which interact with the composition of the channel members 2080 and the base fin structure 212B. The source/drain features 248 may be doped with n-type dopants and/or p-type dopants. Example n-type source/drain features may include Si, GaAs, GaAsP, SiP, or other suitable material and may be in-situ doped during the epitaxial process by introducing an n-type dopant, such as phosphorus (P), arsenic (As), or both. When the source/drain features 248 are not in-situ doped with an n-type dopant, an implantation process (i.e., a junction implant process) may be performed to dope the source/drain features 248 with an n-type dopant. Example p-type source/drain features may include Si, Ge, AlGaAs, SiGe, boron-doped SiGe, or other suitable material and may be in-situ doped during the epitaxial process by introducing a p-type dopant. When the source/drain features 248 are not in-situ doped with a p-type dopant, an implantation process (i.e., a junction implant process) may be performed to dope the source/drain features 248 with a p-type dopant. In some embodiments, the source/drain features 248 include more than one epitaxial semiconductor layer, where the epitaxial semiconductor layers may include the same or different materials and/or the same or different dopant concentrations.

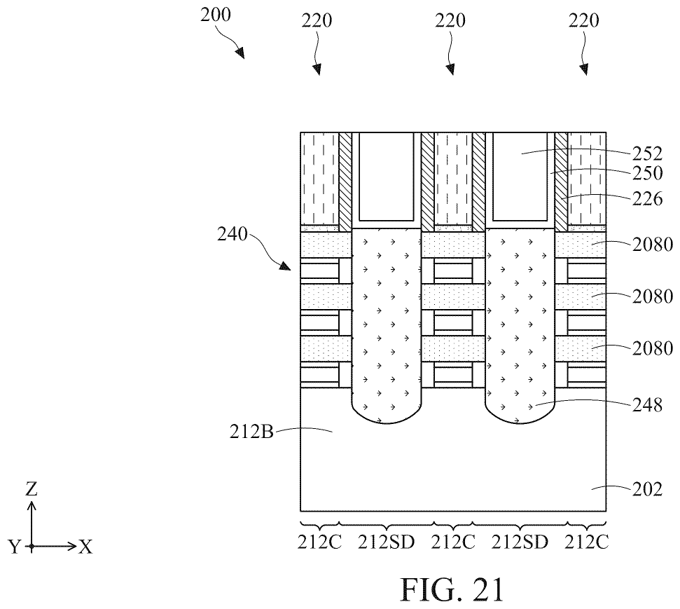

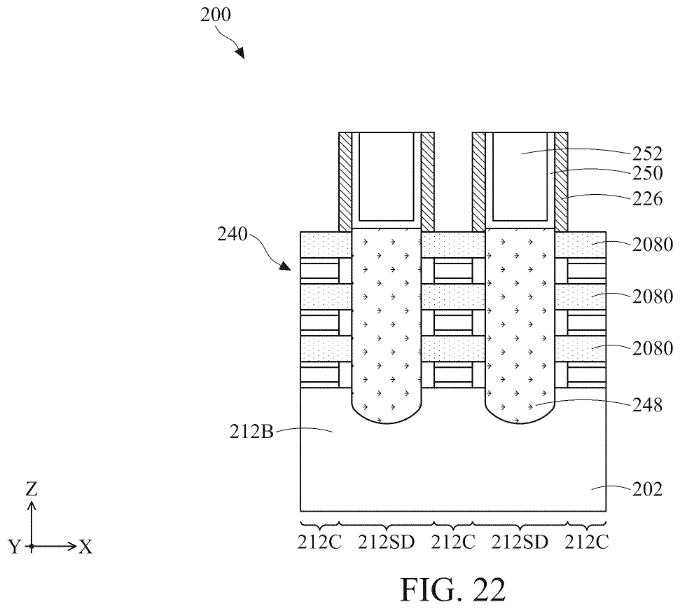

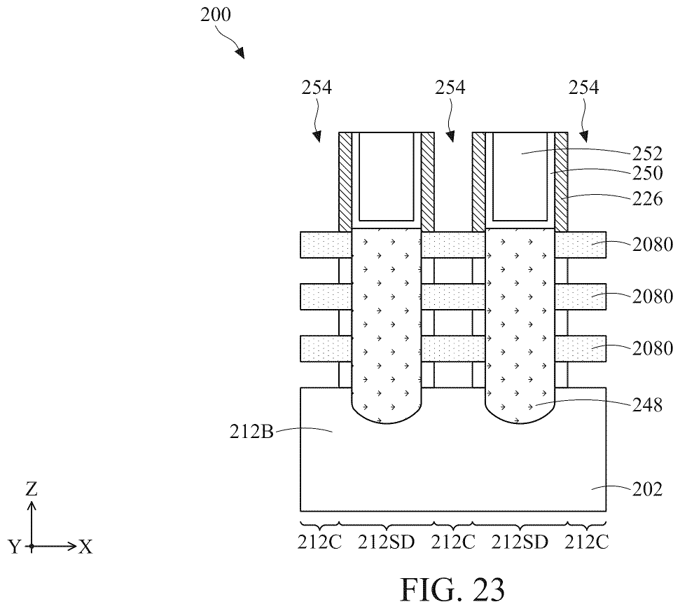

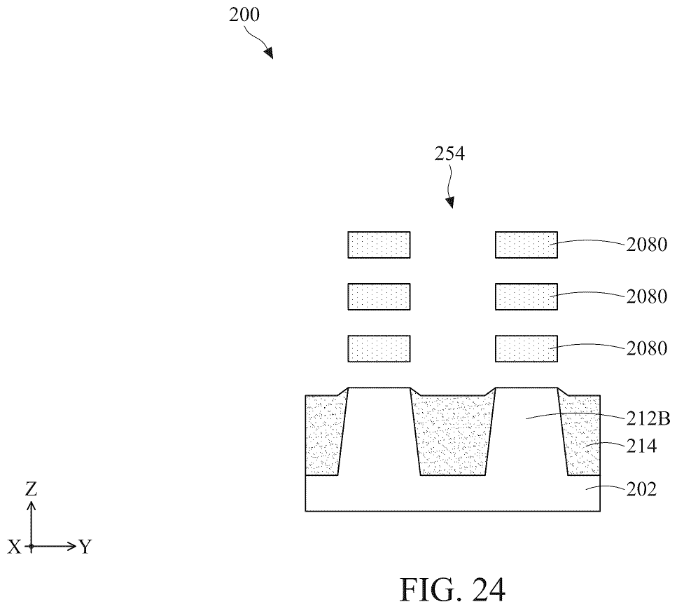

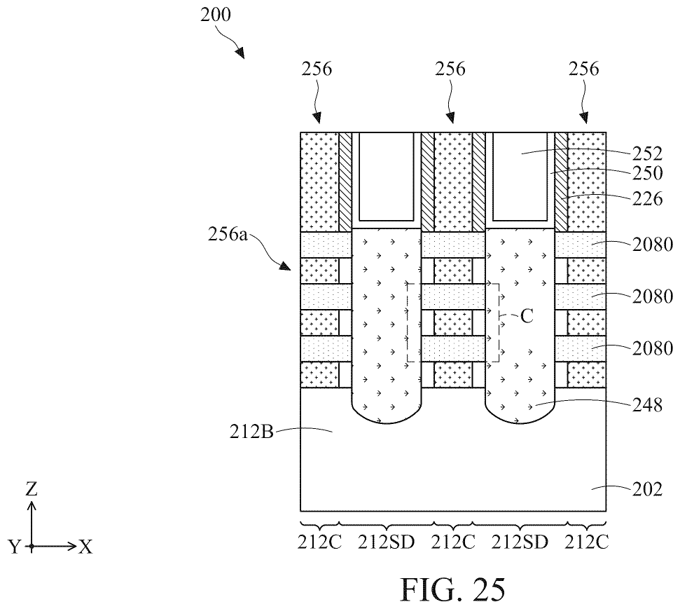

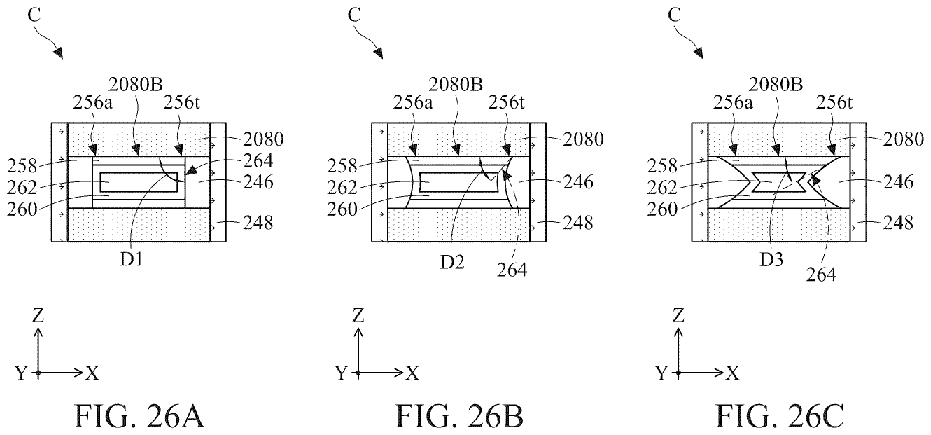

Referring to FIGS. 1 and 21-26C, method 100 includes a block 122 where the dummy gate stack 220 and the combined dummy layer 240 are replaced with a gate structure. Operations at block 122 may include deposition of a contact etch stop layer (CESL) 250 over the source/drain features 248 (shown in FIG. 21), deposition of an interlayer dielectric (ILD) layer 252 over the CESL 250 (shown in FIG. 21), removal of the dummy gate stack 220 (shown in FIG. 22), removal of the combined dummy layer 240 (shown in FIGS. 23 and 24), and deposition of the gate structure 256 to wrap around each of the channel members 2080 (shown in FIGS. 25-26C).

Referring to FIG. 21, the CESL 250 is deposited over the workpiece 200, including over the source/drain feature 248. The CESL 250 may include silicon nitride or aluminum nitride. In some implementations, the CESL 250 may be deposited using CVD or ALD. The ILD layer 252 is then deposited over the CESL 250. In some embodiments, the ILD layer 252 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 252 may be deposited using CVD, FCVD, spin-on coating, or a suitable deposition technique. After the deposition of the ILD layer 252, the workpiece 200 may be planarized by a planarization process to expose the dummy gate stack 220. For example, the planarization process may include a chemical mechanical planarization (CMP) process. Exposure of the dummy gate stack 220 allows the removal of the dummy gate stack 220.

Referring to FIG. 22, the dummy gate stack 220 is removed. The removal of the dummy gate stack 220 may include one or more etching processes that are selective to the material of the dummy gate stack 220. For example, the removal of the dummy gate stack 220 may be performed using a selective wet etch, a selective dry etch, or a combination thereof that is selective to the dummy gate stack 220.

After the removal of the dummy gate stack 220, sidewalls of the channel members 2080 and the combined dummy layer 240 in the channel region 212C are exposed. Referring to FIG. 23, a separate etch process may be performed to selectively remove the combined dummy layer 240 in the channel region 212C. For example, a selective wet etch process or a selective dry etch process may be performed to remove the combined dummy layer 240. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. After the selective removal of the combined dummy layer 240, the channel members 2080 in the channel region 212C are once again exposed as shown in FIGS. 23 and 24. The selective removal of the combined dummy layer 240 forms a gate trench 254 that includes spaces between adjacent channel members 2080.

Referring to FIG. 25, a gate structure 256 is formed to wrap around each of released as channel members 2080. FIGS. 26A-26C illustrate enlarged views of the portion C in the dotted rectangle of the workpiece 200 as in FIG. 25. After the release of the channel members 2080, the gate structure 256 is formed to wrap around each of the channel members 2080. While not explicitly shown in FIG. 25 but shown in FIGS. 26A-26C, the gate structure 256 includes an interfacial layer 258 interfacing the channel members 2080 and the base fin structure 212B in the channel region 212C, a gate dielectric layer 260 over the interfacial layer 258, and a gate electrode layer 262 over the gate dielectric layer 260. The interfacial layer 258 may include a dielectric material such as silicon oxide, hafnium silicate, or silicon oxynitride. The interfacial layer 258 may be formed by chemical oxidation, thermal oxidation, atomic layer deposition (ALD), chemical vapor deposition (CVD), and/or other suitable method. The gate dielectric layer 260 may include a high-k dielectric material, such as hafnium oxide. Alternatively, the gate dielectric layer 260 may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer 260 may be formed by ALD, physical vapor deposition (PVD), CVD, oxidation, and/or other suitable methods.

The gate electrode layer 262 of the gate structure 256 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 262 may include titanium nitride (TIN), titanium aluminum (TiAl), titanium aluminum nitride (TiAl), tantalum nitride (TaN), tantalum aluminum (TaAl), tantalum aluminum nitride (TaAl), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 262 may be formed by ALD, PVD, CVD, e-beam evaporation, or other suitable process. In various embodiments, a CMP process may be performed to remove excessive metal, thereby providing a substantially planar top surface of the gate structure. The gate structure 256 includes portions 256a that interpose between the channel members 2080 in the channel region 212C.

FIGS. 26A-26C correspond to structures presented in FIGS. 19A-19C, respectively. The portion 256a of the gate structure 256 between the neighboring channel members 2080 as in FIGS. 26A-26C tracks the shape of the combined dummy layer 240 as in FIGS. 19A-19C, respectively. In the depicted embodiments, the portion 256a of the gate structure 256, the channel member 2080 (e.g., the top channel member 2080), and the inner spacer feature 246 (e.g., the inner spacer feature 246 on right side) have an intersection. In some embodiments, the portion 256a includes a tip portion 256t at the intersection. The tip portion 256t may only include the interfacial layer 258 as depicted. At the intersection, an angle is formed between a bottom surface 2080B of the channel member 2080 and an interface 264 of the tip portion 256t and the inner spacer feature 246. The angle may be within the portion 256a in the cross-sectional view. For clarity, dashed line 264 in FIGS. 26B and 26C show an extension line of the interface 264. The angle is labeled as D1, D2, and D3 in FIGS. 26A, 26B, and 26C, respectively. D1 may be about 90 degrees. D2 may be about 30 degrees to about 90 degrees. D3 may be about 15 degrees to about 30 degrees. If the angle is too small, for example, less than 15 degrees, a width of the inner spacer feature 246 along the X-direction may be too large, and the inner spacer features 246 on two ends of the portion 256a of the gate structure 256 may merge. If the angle is too large, for example, greater than 90 degrees, a width of the inner spacer feature 246 along the X-direction may be too small, and the isolation between the portions 256a of the gate structure 256 and the source/drain feature 248 may be too small.

The semiconductor device 200 may undergo further processing to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

One of ordinary skill may recognize although FIGS. 3-26C illustrate GAA devices as embodiments, other examples of semiconductor devices may benefit from aspects of the present disclosure.

Although not intended to be limiting, one or more embodiments of the present disclosure provide many benefits to a semiconductor device. For example, the present disclosure provides methods to modify profiles of the inner spacer features by replacing the sacrificial layers with two dummy layers disclosed herein and treating the two dummy layers. Thus, the overall performance of the semiconductor device may be improved.

In one exemplary aspect, the present disclosure is directed to a method. The method includes providing a workpiece including a fin-shaped structure. The fin-shaped structure includes a fin base protruding from a substrate and a stack of channel layers and sacrificial layers disposed over the fin base. The method further includes forming a dummy gate structure over a channel region of the fin-shaped structure, depositing a gate spacer layer over the dummy gate structure, recessing a source/drain region of the fin-shaped structure, selectively removing the sacrificial layers in the channel region to release the channel layers as channel members, depositing a first dummy layer over the channel members, depositing a second dummy layer over the first dummy layer, performing a thermal operation to the workpiece, selectively and partially recessing the first dummy layer and the second dummy layer to form inner spacer recesses among the channel members, forming inner spacer features in the inner spacer recesses, forming a source/drain feature over the source/drain region, removing the dummy gate structure, the first dummy layer, and the second dummy layer, and forming a gate structure to wrap around each of the channel members.

In some embodiments, performing the thermal operation is between depositing the first dummy layer and depositing the second dummy layer, and performing the thermal operation increases etching resistance of the first dummy layer. In some embodiments, performing the thermal operation is after depositing the second dummy layer, and performing the thermal operation increases etching resistance of the first dummy layer and etching resistance of the second dummy layer. In some embodiments, the first dummy layer includes silicon oxide. In some embodiments, during selectively and partially recessing the first dummy layer and the second dummy layer, the first dummy layer has a first etching rate, and the second dummy layer has a second etching rate greater than the first etching rate. In some embodiments, the second dummy layer includes a flowable oxide. In some embodiments, the gate structure includes a bottom portion wrapping around the channel members and a top portion disposed above the channel members and the bottom portion, an angle between a bottom surface of one channel member of the channel members and an interface of the bottom portion of the gate structure and one inner spacer feature of the inner spacer features is about 15 degrees to about 30 degrees, the one inner spacer feature contacts the bottom surface of the channel member. In some embodiments, performing the thermal operation includes performing an annealing process, performing a radical treatment, or a combination thereof.

In another exemplary aspect, the present disclosure is directed to a method. The method includes forming over a substrate a stack that includes a plurality of silicon layers interleaved by a plurality of silicon germanium layers, patterning the stack and the substrate to form a fin-shaped structure having a base portion formed from the substrate and a stack portion formed from the stack, forming a dummy gate structure over a channel region of the fin-shaped structure, recessing a source/drain region of the fin-shaped structure, selectively removing the plurality of silicon germanium layers in the channel region to release the plurality of silicon layers as a plurality of channel members, forming a first dummy layer wrapping around the channel members, forming a second dummy layer wrapping around the first dummy layer, selectively removing a portion of the first dummy layer and the second dummy layer to form inner spacer recesses among the channel members, forming inner spacer features in the inner spacer recesses, forming a source/drain feature over the source/drain region, and replacing the dummy gate structure, the first dummy layer, and the second dummy layer with a metal gate structure.

In some embodiments, the inner spacer features each have a U-shape, a V-shape, or a rectangular shape in a cross-sectional view. In some embodiments, the method further includes performing a thermal operation after forming the first dummy layer and before forming the second dummy layer, the thermal operation increases etching resistance of the first dummy layer. In some embodiments, the method further includes performing a thermal operation after forming the second dummy layer, the thermal operation increases etching resistances of the first dummy layer and the second dummy layer. In some embodiments, the first dummy layer includes an oxide material, and the second dummy layer includes a flowable oxide material. In some embodiments, during selectively removing the portion of the first dummy layer and the second dummy layer, the first dummy layer has a first etching rate, and the second dummy layer has a second etching rate, a ratio of the second etching rate to the first etching rate is about 1:1 to about 1:5. In some embodiments, the first dummy layer has a first thickness, and the second dummy layer has a second thickness greater than the first thickness. In some embodiments, replacing the dummy gate structure, the first dummy layer, and the second dummy layer with the metal gate structure includes removing the dummy gate structure, the first dummy layer, and the second dummy layer, forming an interfacial layer over exposed surfaces of the channel members, thereby forming tip portions between the channel members and the inner spacer features, forming a gate dielectric layer over the interfacial layer, and forming a gate electrode layer over the gate dielectric layer.

In yet another exemplary aspect, the present disclosure is directed to a method. The method includes providing a workpiece. The workpiece includes a stack of channel layers and sacrificial layers, a dummy gate structure disposed over the stack, and a source/drain trench adjacent to the stack and the dummy gate structure. The method further includes replacing the sacrificial layers with a first dummy layer and a second dummy layer. The second dummy layer is spaced apart from the channel layers by the first dummy layer. The method further includes selectively and partially recessing the first dummy layer and the second dummy layer to form inner spacer recesses among the channel layers, forming inner spacer features in the inner spacer recesses, forming a source/drain feature in the source/drain trench, and replacing the dummy gate structure, the first dummy layer, and the second dummy layer with a metal gate structure.

In some embodiments, the inner spacer features each have a U-shape, a V-shape, or a rectangular shape in a cross-sectional view. In some embodiments, the method further includes performing a thermal operation to the workpiece in a gas including oxygen, ammonia, an inert gas, or a combination thereof. In some embodiments, during selectively and partially recessing the first dummy layer and the second dummy layer, the first dummy layer has a first etching rate, and the second dummy layer has a second etching rate, a ratio of the second etching rate to the first etching rate is about 1:1 to about 1:5.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a workpiece including a fin-shaped structure, wherein the fin-shaped structure includes a fin base protruding from a substrate and a stack of channel layers and sacrificial layers disposed over the fin base;
forming a dummy gate structure over a channel region of the fin-shaped structure;
depositing a gate spacer layer over the dummy gate structure;
recessing a source/drain region of the fin-shaped structure;
selectively removing the sacrificial layers in the channel region to release the channel layers as channel members;
depositing a first dummy layer over the channel members;
depositing a second dummy layer over the first dummy layer;
performing a thermal operation to the workpiece;
selectively and partially recessing the first dummy layer and the second dummy layer to form inner spacer recesses among the channel members;
forming inner spacer features in the inner spacer recesses;
forming a source/drain feature over the source/drain region;
removing the dummy gate structure, the first dummy layer, and the second dummy layer; and
forming a gate structure to wrap around each of the channel members.

2. The method of claim 1, wherein performing the thermal operation is between depositing the first dummy layer and depositing the second dummy layer, and
wherein performing the thermal operation increases etching resistance of the first dummy layer.

3. The method of claim 1, wherein performing the thermal operation is after depositing the second dummy layer, and
wherein performing the thermal operation increases etching resistance of the first dummy layer and etching resistance of the second dummy layer.

4. The method of claim 1, wherein the first dummy layer includes silicon oxide.

5. The method of claim 1, wherein during selectively and partially recessing the first dummy layer and the second dummy layer, the first dummy layer has a first etching rate, and the second dummy layer has a second etching rate greater than the first etching rate.

6. The method of claim 1, wherein the second dummy layer includes a flowable oxide.

7. The method of claim 1, wherein the gate structure includes a bottom portion wrapping around the channel members and a top portion disposed above the channel members and the bottom portion,
wherein an angle between a bottom surface of one channel member of the channel members and an interface of the bottom portion of the gate structure and one inner spacer feature of the inner spacer features is about 15 degrees to about 30 degrees,
wherein the one inner spacer feature contacts the bottom surface of the channel member.

8. The method of claim 1, wherein performing the thermal operation includes performing an annealing process, performing a radical treatment, or a combination thereof.

9. A method, comprising:
forming over a substrate a stack that includes a plurality of silicon layers interleaved by a plurality of silicon germanium layers;
patterning the stack and the substrate to form a fin-shaped structure having a base portion formed from the substrate and a stack portion formed from the stack;
forming a dummy gate structure over a channel region of the fin-shaped structure;
recessing a source/drain region of the fin-shaped structure;
selectively removing the plurality of silicon germanium layers in the channel region to release the plurality of silicon layers as a plurality of channel members;
forming a first dummy layer wrapping around the channel members;
forming a second dummy layer wrapping around the first dummy layer;
selectively removing a portion of the first dummy layer and the second dummy layer to form inner spacer recesses among the channel members;
forming inner spacer features in the inner spacer recesses;
forming a source/drain feature over the source/drain region; and
replacing the dummy gate structure, the first dummy layer, and the second dummy layer with a metal gate structure.

10. The method of claim 9, wherein the inner spacer features each have a U-shape, a V-shape, or a rectangular shape in a cross-sectional view.

11. The method of claim 9, further comprising performing a thermal operation after forming the first dummy layer and before forming the second dummy layer, wherein the thermal operation increases etching resistance of the first dummy layer.

12. The method of claim 9, further comprising performing a thermal operation after forming the second dummy layer,
wherein the thermal operation increases etching resistances of the first dummy layer and the second dummy layer.

13. The method of claim 9, wherein the first dummy layer includes an oxide material, and
wherein the second dummy layer includes a flowable oxide material.

14. The method of claim 9, wherein during selectively removing the portion of the first dummy layer and the second dummy layer, the first dummy layer has a first etching rate, and the second dummy layer has a second etching rate,
wherein a ratio of the second etching rate to the first etching rate is about 1:1 to about 1:5.

15. The method of claim 9, wherein the first dummy layer has a first thickness, and the second dummy layer has a second thickness greater than the first thickness.

16. The method of claim 9, wherein replacing the dummy gate structure, the first dummy layer, and the second dummy layer with the metal gate structure includes:
removing the dummy gate structure, the first dummy layer, and the second dummy layer,
forming an interfacial layer over exposed surfaces of the channel members, thereby forming tip portions between the channel members and the inner spacer features,
forming a gate dielectric layer over the interfacial layer, and
forming a gate electrode layer over the gate dielectric layer.

17. A method, comprising:
providing a workpiece, wherein the workpiece includes a stack of channel layers and sacrificial layers, a dummy gate structure disposed over the stack, and a source/drain trench adjacent to the stack and the dummy gate structure;
replacing the sacrificial layers with a first dummy layer and a second dummy layer, wherein the second dummy layer is spaced apart from the channel layers by the first dummy layer;
selectively and partially recessing the first dummy layer and the second dummy layer to form inner spacer recesses among the channel layers;
forming inner spacer features in the inner spacer recesses;
forming a source/drain feature in the source/drain trench; and
replacing the dummy gate structure, the first dummy layer, and the second dummy layer with a metal gate structure.

18. The method of claim 17, wherein the inner spacer features each have a U-shape, a V-shape, or a rectangular shape in a cross-sectional view.

19. The method of claim 17, further comprising performing a thermal operation to the workpiece in a gas including oxygen, ammonia, an inert gas, or a combination thereof.

20. The method of claim 17, wherein during selectively and partially recessing the first dummy layer and the second dummy layer, the first dummy layer has a first etching rate, and the second dummy layer has a second etching rate,
wherein a ratio of the second etching rate to the first etching rate is about 1:1 to about 1:5.
